(19) United States
(12) Patent Application Publication
(10) Pub. No.: US 2026/0287624 A1
(43) Pub. Date: Sep. 24, 2026

(54) VOLTAGE ESTIMATION DEVICE AND VOLTAGE ESTIMATION METHOD

(71) Applicant: HONDA MOTOR CO., LTD., TOKYO (JP)

(72) Inventors: Masahiro YOSHIZAWA, WAKO-SHI (JP); Takuma YAMAWAKI, WAKO-SHI (JP)

(21) Appl. No.: 19/574,770

(22) Filed: Mar. 23, 2026

(30) Foreign Application Priority Data
Mar. 24, 2025 (JP) 2025-047969

(51) Int. Cl. G01R 19/00; H01M 10/42

(52) U.S. Cl. CPC G01R 19/0046; H01M 10/4285

(57) ABSTRACT

A voltage estimation device includes a voltage acquisition unit that acquires an output voltage output by a first cell group containing one or more unit cells and one or more dummy cells, the unit cells and the dummy cells being connected in series, the unit cells being configured to generate electric power using a fuel gas and an oxygen-containing gas, the dummy cells being configured not to generate electric power, and a voltage estimation unit that estimates a cell voltage of each unit cell based on the output voltage and a unit amount of voltage drop per dummy cell.

### CROSS-REFERENCE TO RELATED APPLICATIONS

This application is based upon and claims the benefit of priority from Japanese Patent Application No. 2025-047969 filed on Mar. 24, 2025, the contents of which are incorporated herein by reference.

### BACKGROUND OF THE INVENTION

### Field of the Invention

The present disclosure relates to a voltage estimation device and a voltage estimation method.

### Description of the Related Art

In recent years, research and development have been conducted on fuel cells that contribute to energy efficiency in order to ensure that more people have access to affordable, reliable, sustainable and modern energy. WO 2013/108369 A1 discloses a fuel cell system including a cell monitor capable of detecting a group voltage for each group containing a plurality of cells.

### SUMMARY OF THE INVENTION

When the fuel cell stack includes a dummy cell that does not generate power together with a unit cell that can generate power, a decrease in the cell voltage of each unit cell may be erroneously detected. In this case, a control operation that would otherwise be unnecessary is activated in order to compensate for the erroneously detected cell-voltage drop.

The present disclosure aims to solve the above-described problem, and thus contributes to improved energy efficiency.

A first aspect of the present disclosure is a voltage estimation device including: a voltage acquisition unit configured to acquire an output voltage output by a first cell group containing one or more unit cells and one or more dummy cells, the unit cells and the dummy cells being connected in series, the unit cells being configured to generate electric power using a fuel gas and an oxygen-containing gas, the dummy cells being configured not to generate electric power; and a voltage estimation unit configured to estimate a cell voltage of each of the unit cells based on the output voltage and a unit amount of voltage drop per dummy cell.

A second aspect of the present disclosure is a voltage estimation method including: a voltage acquisition step of acquiring an output voltage output by a first cell group containing one or more unit cells and one or more dummy cells, the unit cells and the dummy cells being connected in series, the unit cells being configured to generate electric power using a fuel gas and an oxygen-containing gas, the dummy cells being configured not to generate electric power; and a voltage estimation step of estimating a cell voltage of each of the unit cells based on the output voltage and a unit amount of voltage drop per dummy cell.

According to the present disclosure, the activation of unnecessary control operation in the fuel cell stack can be suppressed.

The above and other objects, features, and advantages of the present invention will become more apparent from the following description when taken in conjunction with the accompanying drawings, in which a preferred embodiment of the present invention is shown by way of illustrative example.

### BRIEF DESCRIPTION OF THE DRAWINGS

FIG. 1 is a diagram for explaining cell groups of a fuel cell stack and a voltage estimation device that estimates a cell voltage of each unit cell;

FIG. 2 is a diagram for explaining estimation of the cell voltage of each unit cell;

FIG. 3 is a flowchart illustrating a processing procedure according to a voltage estimation method for estimating the cell voltage of each unit cell;

FIG. 4 is a diagram for explaining acquisition of a current value of a power generation current;

FIG. 5 is a diagram illustrating a setting table in which a unit amount of voltage drop is set;

FIG. 6A is a diagram for explaining cell groups of a fuel cell stack;

FIG. 6B is a diagram for explaining estimation of the cell voltage of each unit cell;

FIG. 7A is a diagram for explaining cell groups of a fuel cell stack; and

FIG. 7B is a diagram for explaining estimation of the cell voltage of each unit cell.

### DETAILED DESCRIPTION OF THE INVENTION

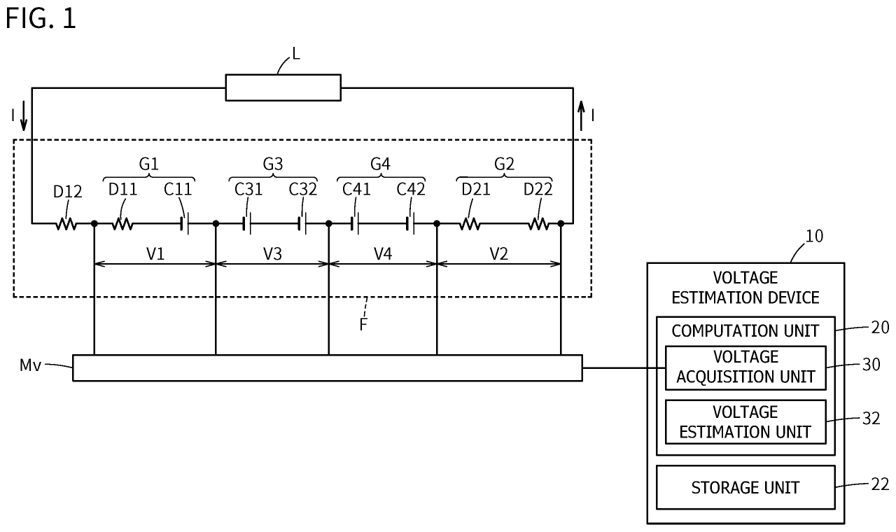

FIG. 1 is a diagram for explaining cell groups G of a fuel cell stack F and a voltage estimation device 10 that estimates a cell voltage Vc of each unit cell C. In order to supply power to be consumed by a load device L, a closed circuit including the fuel cell stack F and the load device L is formed. A power generation current I of the fuel cell stack F flows through the closed circuit. When the fuel cell stack F is mounted on a vehicle, the load device L is, for example, a motor.

The fuel cell stack F includes a plurality of cells. The plurality of cells include unit cells C capable of generating power using fuel gas and oxygen-containing gas, and dummy cells D that do not generate power. The plurality of dummy cells D are disposed at both ends of the fuel cell stack F. That is, one or more dummy cells D are disposed at one end of the fuel cell stack F, and one or more dummy cells D are disposed at the other end of the fuel cell stack F. When a plurality of dummy cells D are disposed at each end of the fuel cell stack F, the plurality of dummy cells D disposed at each end are equivalent to a plurality of electrical resistances connected in series with each other.

The plurality of unit cells C are arranged between the dummy cells D arranged at both ends of the fuel cell stack F. The plurality of unit cells C are connected in series with each other. The dummy cells D are disposed at both ends of the fuel cell stack F, and thus perform the following functions. First, the dummy cell D functions to block moisture (water content) entering the fuel cell stack F from outside of the fuel cell stack F through the flow path of fuel gas or the flow path of oxygen-containing gas, at a stage upstream of the unit cell C. The dummy cell D also serves to maintain the elevated temperature inside the fuel cell stack F, which is raised by power generation of the unit cell C.

In the example shown in FIG. 1, two dummy cells D are disposed at each of both ends of the fuel cell stack F. Two dummy cells D11, D12 connected in series with each other are arranged at one of the opposite ends of the fuel cell stack F. Two dummy cells D21 and D22 connected in series with each other are disposed at the other of the opposite ends of the fuel cell stack F. Five unit cells C11, C31, C32, C41, and C42 are arranged between two dummy cells D11, D12 and two dummy cells D21, D22 That is, an odd number of unit cells C are connected in series.

The fuel cell stack F includes a plurality of cell groups G. The cell group G includes the plurality of cells described above. The plurality of cell groups G include a first cell group G1 and a second cell group G2. The first cell group G1 includes one or more unit cells C and one or more dummy cells D. In the first cell group G1, the one or more unit cells C and the one or more dummy cells D are connected in series. The second cell group G2 includes only a plurality of dummy cells D. In the second cell group G2, the plurality of dummy cells D are connected in series.

The plurality of cell groups G described above may include another cell group G different from the first cell group G1 and the second cell group G2. The other cell group G includes only a plurality of unit cells C. In the other cell group G, the plurality of unit cells C are connected in series. A third cell group G3 and a fourth cell group G4, which will be described later, both correspond to the other cell group G described above.

In the example illustrated in FIG. 1, each cell group G includes two cells. As described above, an odd number of the unit cells C are connected in series. Therefore, the plurality of cell groups G included in the fuel cell stack F include the first cell group G1 in which one unit cell C and one dummy cell D are connected in series. The plurality of cell groups G include the second cell group G2 in which only two dummy cells D are connected in series. Further, the plurality of cell groups G include the third cell group G3 and the fourth cell group G4 each in which only two unit cells C are connected in series.

In the first cell group G1, the unit cell C11 and the dummy cell D11 are connected in series. In the second cell group G2, the dummy cells D21 and D22 are connected in series. In the third cell group G3, the unit cells C31 and C32 are connected in series. In the fourth cell group G4, the unit cells C41 and C42 are connected in series.

A voltage measurement unit Mv measures the voltage for each cell group G of the fuel cell stack F. When a cell group G includes one or more unit cells C as in the first cell group G1 and the other cell groups G described above, the voltage measurement unit Mv measures the output voltage outputted by the cell group G. When a cell group G includes only the dummy cell(s) D as in the second cell group G2, the voltage measurement unit Mv measures the voltage drop across the cell group G.

In the example illustrated in FIG. 1, each cell group G includes two cells. Therefore, the voltage measurement unit Mv, which measures the voltage for each cell group G, measures the voltage across the two cells. To be specific, the voltage measurement unit Mv measures the voltage across the first cell group G1. As a result, the output voltage V1 of the first cell group G1 is measured. The voltage measurement unit Mv measures the voltage across the second cell group G2. Accordingly, the voltage drop V2 due to the second cell group G2 is measured.

The voltage measurement unit Mv measures the voltage across the third cell group G3. As a result, the output voltage V3 of the third cell group G3 is measured. The voltage measurement unit Mv measures the voltage across the fourth cell group G4. As a result, the output voltage V4 of the fourth cell group G4 is measured.

In the example shown in FIG. 1, the first cell group G1 includes one dummy cell D in addition to one unit cell C. Therefore, the output voltage V1 of the first cell group G1 is lower than the cell voltage Vc of the unit cell C. In this case, there is a possibility that the occurrence of an abnormality in which the cell voltage Vc of the unit cell C included in the first cell group G1 decreases may be erroneously detected.

As a result of such erroneous detection, a predetermined control operation may be activated in the fuel cell stack F. As a typical factor that causes a decrease in the cell voltage Vc of the unit cell C, for example, the presence of moisture entering the fuel cell stack F can be considered. Therefore, as the above-described predetermined control operation, for example, a control operation for increasing the amount of oxygen-containing gas supplied to the fuel cell stack F may be activated. By increasing the supply amount of the oxygen-containing gas, removal of moisture (water content) can be expected.

However, the cause of the low output voltage V1 of the first cell group G1 is not the ingress of moisture into the fuel cell stack F. The cause lies in the fact that the first cell group G1 includes the dummy cell D together with the unit cell C. Therefore, the activation of the above-described predetermined control operation is unnecessary. As such, as described later, the cell voltage Vc of each unit cell C is estimated by the voltage estimation device 10. This suppresses the activation of an unnecessary control operation in the fuel cell stack F.

FIG. 1 is a block diagram illustrating a configuration of the voltage estimation device 10. The voltage estimation device 10 includes a computation unit 20 and a storage unit 22. The computation unit 20 is a computer and includes a processor such as a central processing unit (CPU) or a graphics processing unit (GPU). That is, the computation unit 20 includes processing circuitry.

The storage unit 22 is a computer-readable storage medium. The storage unit 22 includes a volatile memory such as a random access memory (RAM) and a nonvolatile memory such as a read only memory (ROM) or a flash memory. The volatile memory is used as a working memory of the processor. The nonvolatile memory stores a computer program executed by the processor and other necessary data.

The computer program (computer software) executed by the processor may also be referred to as a computer program product. The computer program product is not limited to a computer program stored in a storage medium, and includes a computer program transmitted, distributed, or downloaded via the Internet or the like.

The computation unit 20 includes a voltage acquisition unit 30 and a voltage estimation unit 32. The computation unit 20 executes the computer program stored in the storage unit 22, thereby implementing the voltage acquisition unit 30 and the voltage estimation unit 32. At least a part of the voltage acquisition unit 30 and the voltage estimation unit 32 may be realized by an integrated circuit such as an application specific integrated circuit (ASIC) or a field programmable gate array (FPGA), or an electronic circuit including a discrete device.

The voltage acquisition unit 30 acquires the output voltage V1 of the first cell group G1 from the voltage measurement unit Mv. In the present embodiment, the voltage acquisition unit 30 further acquires the voltage drop V2 due to the second cell group G2 and the output voltage of the other cell groups G described above, from the voltage measurement unit Mv. In the example shown in FIG. 1, the output voltage V3 and the output voltage V4 of the third cell group G3 and the fourth cell group G4 are acquired as the output voltage of the other cell groups G.

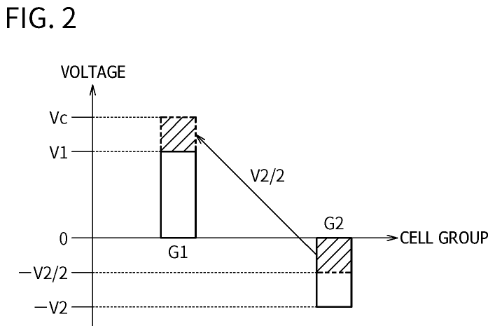

The voltage estimation unit 32 estimates the cell voltage Vc of each unit cell C, based on the output voltage V1 of the first cell group G1 and a unit amount of voltage drop per dummy cell D. As described later with reference to FIG. 2 and the like, the unit amount of voltage drop is obtained by dividing the voltage drop V2 due to the second cell group G2 by the number of dummy cells D included in the second cell group G2. Accordingly, the output voltage V1 output by the first cell group G1 including one or more unit cells C and one or more dummy cell D can be accurately corrected, and the cell voltage Vc of the unit cell C included in the first cell group G1 can thus be estimated.

The voltage estimation unit 32 acquires a correction amount by multiplying the unit amount of voltage drop by the number of the plurality of dummy cells D included in the first cell group G1. The voltage estimating unit 32 adds the correction amount to the output voltage V1 obtained by the voltage acquisition unit 30, thereby obtaining a corrected voltage. The voltage estimation unit 32 estimates the cell voltage Vc using the corrected voltage and the number of unit cells C included in the first cell group G1. The cell voltage Vc is obtained by dividing the corrected voltage by the number of unit cells C included in the first cell group G1. The estimation of the cell voltage Vc in the example shown in FIG. 1 will be described later with reference to FIG. 2.

That is, the voltage estimation device 10 estimates the cell voltage Vc of each unit cell C by correcting the output voltage V1 of the first cell group G1 using the unit amount of voltage drop. Accordingly, the possibility of erroneously detecting the occurrence of an abnormality in which the cell voltage Vc of the unit cell C included in the first cell group G1 decreases is reduced. This suppresses the activation of an unnecessary control operation in the fuel cell stack F.

The voltage estimation device 10 further divides the output voltage of the other cell group G including only the unit cells C by the number of the unit cells C included in the cell group G. Thus, the voltage estimation device 10 estimates the cell voltage Vc of each unit cell C.

That is, the voltage estimation device 10 estimates the cell voltage Vc by dividing the output voltage V3 of the third cell group G3 by the number (i.e., 2) of unit cells C included in the third cell group G3. The voltage estimation device 10 estimates the cell voltage Vc by dividing the output voltage V4 of the fourth cell group G4 by the number (i.e., 2) of unit cells C included in the fourth cell group G4. In this manner, the voltage estimation device 10 estimates the cell voltage Vc of each unit cell C included in the fuel cell stack F.

FIG. 2 is a diagram for explaining estimation of the cell voltage Vc of each unit cell C. Here, the estimation of the cell voltage Vc will be described with reference to the example shown in FIG. 1. The first cell group G1 shown in FIG. 1 includes one unit cell C11 and one dummy cell D11. That is, the number of the unit cells C included in the first cell group G1 is one, and the number of the dummy cells D included therein is also one. The second cell group G2 shown in FIG. 1 includes two dummy cells D. That is, the number of the dummy cells D included in the second cell group G2 is two.

The unit amount of voltage drop described above is obtained by dividing the voltage drop V2 due to the second cell group G2 by 2, which is the number of the dummy cells D included in the second cell group G2. Therefore, the unit amount of voltage drop is V2/2. The correction amount described above is obtained by multiplying the unit amount of voltage drop by 1, which is the number of the dummy cells D included in the first cell group G1. Therefore, the correction amount is V2/2. The above-described corrected voltage is obtained by adding the correction amount to the output voltage V1. Therefore, the corrected voltage is V1+V2/2.

The cell voltage Vc is obtained by dividing the corrected voltage by 1, which is the number of the unit cells C included in the first cell group G1. Therefore, the cell voltage Vc is V1+V2/2. Accordingly, the output voltage V1 output by the first cell group G1 including one or more unit cells C and one or more dummy cell D can be accurately corrected, and the cell voltage Vc of the unit cell C included in the first cell group G1 can thus be estimated.

When the first cell group G1 includes one unit cell C11 and one dummy cell D11, the voltage estimation unit 32 may estimate the cell voltage Vc by adding the unit amount of voltage drop V2/2 to the output voltage V1. According to such a configuration, it is possible to easily estimate the cell voltage Vc of the unit cell C included in the first cell group G1 that includes one unit cell C and one dummy cell D.

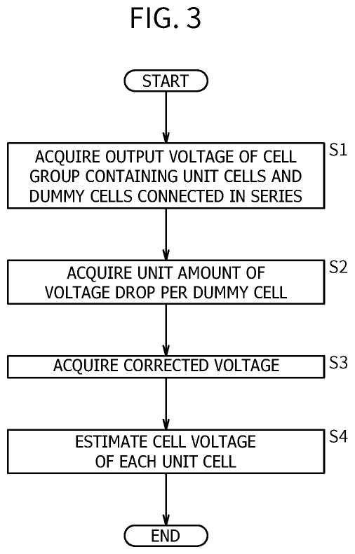

FIG. 3 is a flowchart illustrating a processing procedure according to a voltage estimation method for estimating the cell voltage Vc of each unit cell C. This processing procedure is performed by the computation unit 20 executing a computer program stored in the storage unit 22 of the voltage estimation device 10. When the procedure is started, the voltage acquisition unit 30, in step S1, acquires the output voltage output by the cell group G in which the unit cell C and the dummy cell D are connected in series. In the example shown in FIG. 1, the voltage acquisition unit 30 acquires the output voltage V1 of the first cell group G1.

In step S2, the voltage estimation unit 32 acquires the unit amount of voltage drop per dummy cell D. In step S3, the voltage estimation unit 32 acquires the above-described correction amount based on the unit amount of voltage drop. The voltage estimation unit 32 acquires the corrected voltage based on the correction amount and the output voltage (the output voltage V1 of the first cell group G1) acquired in step S1.

In step S4, the voltage estimation unit 32 estimates the cell voltage Vc of each unit cell C included in the cell group G (the first cell group G1) including the unit cell C and the dummy cell D, based on the corrected voltage acquired in step S3. The voltage estimation unit 32 further estimates the cell voltage Vc of each unit cell C included in another cell group G that includes only the unit cell C, based on the output voltage of the other cell group G. When the process of step S4 is completed, the present processing procedure is terminated.

The above-described embodiment may be modified as follows. In the following modifications, the description overlapping with the above-described embodiment will be omitted.

### (Modification 1)

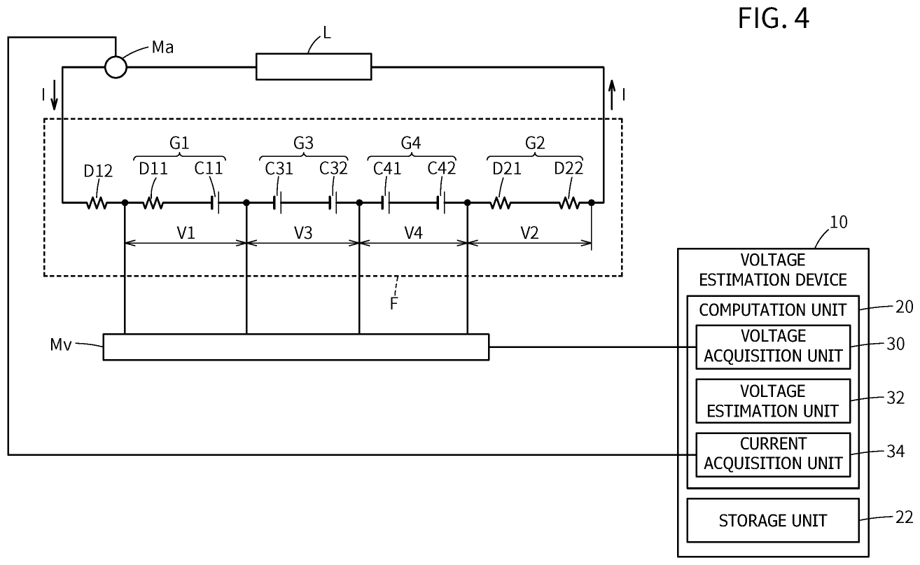

In the above-described embodiment, the voltage drop V2 due to the second cell group G2 is measured by the voltage measurement unit Mv. The voltage acquisition unit 30 acquires the voltage drop V2 from the voltage measurement unit Mv. The voltage estimation unit 32 acquires the unit amount of voltage drop per dummy cell D. However, the acquisition of the unit amount of voltage drop is not limited to this. The unit amount of voltage drop may be acquired using a current value of the power generation current I of the fuel cell stack F. FIG. 4 is a diagram for explaining acquisition of the current value of the power generation current I.

As described above, the power generation current I of the fuel cell stack F flows through a closed circuit including the fuel cell stack F and the load device L. In the example shown in FIG. 4, a current measurement unit Ma that measures the current value of the power generation current I is provided in the closed circuit.

The computation unit 20 of the voltage estimation device 10 further includes a current acquisition unit 34 in addition to the voltage acquisition unit 30 and the voltage estimation unit 32 described above. The current acquisition unit 34 is also realized by the computation unit 20 executing a computer program stored in the storage unit 22. The current acquisition unit 34 may also be realized by an integrated circuit such as an ASIC or an FPGA, or an electronic circuit including a discrete device. The current acquisition unit 34 acquires the current value of the power generation current I of the fuel cell stack F including a plurality of cell groups G.

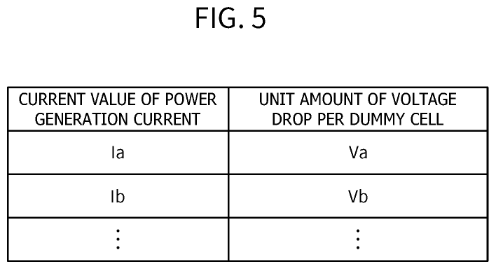

FIG. 5 is a diagram illustrating a setting table in which a unit amount of voltage drop is set. The setting table is stored in the storage unit 22 in advance. The power generation current I of the fuel cell stack F described above flows through the second cell group G2 including only the dummy cells D. The number of the dummy cells D included in the second cell group G2 is determined in advance. As described above, since the dummy cell D is equivalent to an electrical resistance, the resistance value of the electrical resistance causing the voltage drop in the second cell group G2 is determined in advance.

Therefore, the unit amount of voltage drop per dummy cell D can be calculated in advance according to the current value of the power generation current I. The unit amount of voltage drop calculated in advance in this manner is set in the setting table shown in FIG. 5 in association with the power generation current I. In the example shown in FIG. 5, the unit amount of voltage drop Va is set with respect to the current value Ia of the power generation current I. Further, the unit amount of voltage drop Vb is set with respect to the current value Ib of the power generation current I. The voltage estimation unit 32 acquires the unit amount of voltage drop per dummy cell D1 from the setting table based on the current value of the power generation current I acquired by the current acquisition unit 34.

The voltage estimation unit 32 estimates the cell voltage Vc of the unit cell C included in the first cell group G1 based on the unit amount of voltage drop acquired from the setting table and the output voltage V1 acquired by the voltage acquisition unit 30. The fuel cell stack F is usually provided with a current measurement unit Ma that measures the current value of the power generation current I. Since that current measurement unit Ma is used, it is not necessary to provide the voltage measurement unit Mv with a voltage measurement circuit for measuring the voltage drop V2 due to the second cell group G2 including only the dummy cells D.

### (Modification 2)

In the above-described embodiment, each cell group G includes two cells. The voltage measurement unit Mv measures the voltage across two cells in order to measure the voltage for each cell group G. However, the cell group G may include three or more cells. The voltage measurement unit Mv measures the voltage of each cell group G, and therefore measures the voltage across the number of cells included in each cell group G. In the second modification, an example in which each cell group G includes three cells will be described, but the same applies to an example in which each cell group G includes more than three cells.

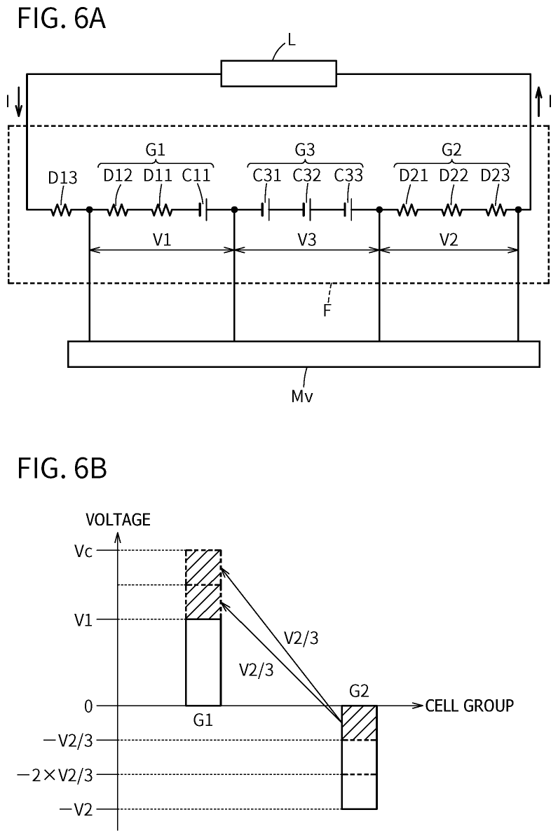

FIG. 6A is a diagram for explaining the cell groups G of the fuel cell stack F. In the example shown in FIG. 6A, three dummy cells D are disposed at each of the opposite ends of the fuel cell stack F. Three dummy cells D11, D12, D13 connected in series are arranged at one of the opposite ends of the fuel cell stack F. Three dummy cells D21, D22, and D23 connected in series are disposed at the other of the opposite ends of the fuel cell stack F. Four unit cells C11, C31, C32, and C33 are arranged between the three dummy cells D11, D12, D13 and the three dummy cells D21, D22, D23.

The fuel cell stack F includes a plurality of the cell groups G. Each of the cell groups G includes three cells. The plurality of cell groups G include a first cell group G1 and a second cell group G2. The first cell group G1 includes one or more unit cells C and one or more dummy cells D. In the example shown in FIG. 6A, in the first cell group G1, one unit cell C11, two dummy cells D11 and D12 are connected in series. The second cell group G2 includes only a plurality of dummy cells D. In the example shown in FIG. 6A, three dummy cells D21, D22, and D23 are connected in series in the second cell group G2.

The plurality of cell groups G of the fuel cell stack F as described above further include a third cell group G3. The third cell group G3 includes only a plurality of unit cells C. In the example shown in FIG. 6A, three unit cells C31, C32, and C33 are connected in series in the third cell group G3.

As described above, each of the cell groups G includes three cells. Therefore, the voltage measurement unit Mv, which measures the voltage of each cell group G, measures the voltage across the three cells. To be specific, the voltage measurement unit Mv measures the voltage across the first cell group G1. As a result, the output voltage V1 of the first cell group G1 is measured. The voltage measurement unit Mv measures the voltage across the second cell group G2. Accordingly, the voltage drop V2 due to the second cell group G2 is measured. The voltage measurement unit Mv measures the voltage across the third cell group G3. As a result, the output voltage V3 of the third cell group G3 is measured.

In the example shown in FIG. 6A, the number of the unit cells C included in the third cell group G3 is three. The number of the unit cells C included in the first cell group G1 is one. Therefore, the output voltage V1 of the first cell group G1 is lower than the output voltage V3 of the third cell group G3.

FIG. 6B is a diagram for explaining estimation of the cell voltage Vc of each unit cell C. Here, the estimation of the cell voltage Vc will be described with reference to the example shown in FIG. 6A. The first cell group G1 shown in FIG. 6A includes one unit cell C11 and two dummy cells D11, D12. That is, the number of the unit cells C included in the first cell group G1 is one, and the number of the dummy cells D included therein is two. The second cell group G2 shown in FIG. 6A includes three dummy cells D. That is, the number of the dummy cells D included in the second cell group G2 is three.

The unit amount of voltage drop described above is obtained by dividing the voltage drop V2 due to the second cell group G2 by 3, which is the number of the dummy cells D included in the second cell group G2. Therefore, the unit amount of voltage drop is V2/3. The correction amount described above is obtained by multiplying the unit amount of voltage drop by 2, which is the number of the dummy cells D included in the first cell group G1. Therefore, the correction amount is 2×V2/3. The above-described corrected voltage is obtained by adding the correction amount to the output voltage V1. Therefore, the corrected voltage is V1+2×V2/3.

The cell voltage Vc is obtained by dividing the corrected voltage by 1, which is the number of the unit cells C included in the first cell group G1. Therefore, the cell voltage Vc is V1+2×V2/3. Accordingly, the output voltage V1 output by the first cell group G1 including one or more unit cells C and one or more dummy cell D can be accurately corrected, and the cell voltage Vc of the unit cell C included in the first cell group G1 can thus be estimated.

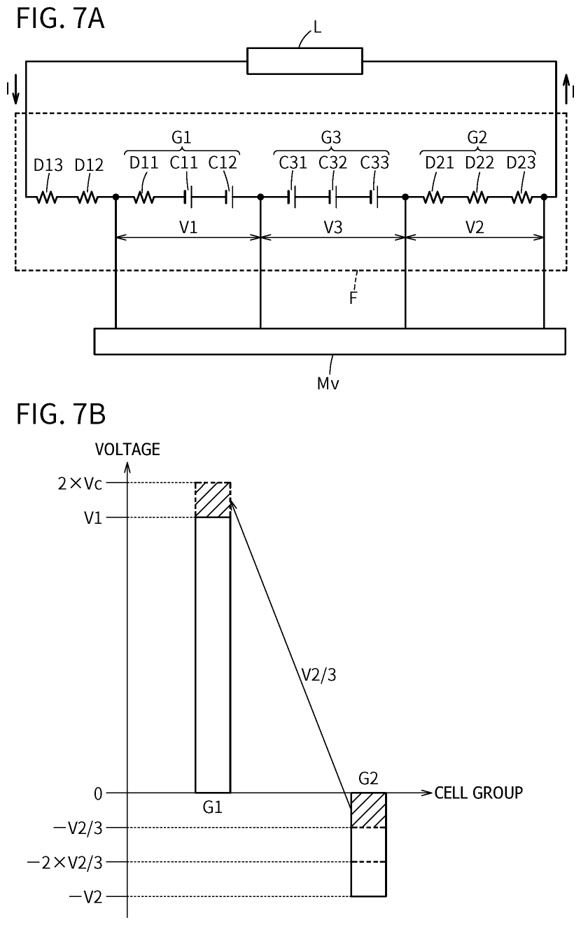

FIG. 7A is a diagram for explaining the cell groups G of the fuel cell stack F. In the example shown in FIG. 7A, three dummy cells D are disposed at each of the opposite ends of the fuel cell stack F. Three dummy cells D11, D12, D13 connected in series are arranged at one of the opposite ends of the fuel cell stack F. Three dummy cells D21, D22, and D23 connected in series are disposed at the other of the opposite ends of the fuel cell stack F.

Five unit cells C11, C12, C31, C32, and C33 are arranged between the three dummy cells D11, D12, D13 and the three dummy cells D21, D22, D23.

The fuel cell stack F includes a plurality of the cell groups G. Each of the cell groups G includes three cells. The plurality of cell groups G include a first cell group G1 and a second cell group G2. The first cell group G1 includes one or more unit cells C and one or more dummy cells D. In the example shown in FIG. 7A, in the first cell group G1, two unit cells C11 and C12 and one dummy cell D11 are connected in series. The second cell group G2 includes only a plurality of dummy cells D. In the example shown in FIG. 7A, three dummy cells D21, D22, and D23 are connected in series in the second cell group G2.

The plurality of cell groups G of the fuel cell stack F as described above further include a third cell group G3. The third cell group G3 includes only a plurality of unit cells C. In the example shown in FIG. 7A, three unit cells C31, C32, and C33 are connected in series in the third cell group G3.

As described above, each of the cell groups G includes three cells. Therefore, the voltage measurement unit Mv, which measures the voltage of each cell group G, measures the voltage across the three cells. The details of the voltage measurement performed by the voltage measurement unit Mv are the same as those described above with reference to FIG. 6A. In this way, the voltage measurement unit Mv measures the output voltage V1 of the first cell group G1, the voltage drop V2 due to the second cell group G2, and the output voltage V3 of the third cell group G3.

In the example shown in FIG. 7A, the number of the unit cells C included in the third cell group G3 is three. The number of the unit cells C included in the first cell group G1 is two. Therefore, the output voltage V1 of the first cell group G1 is lower than the output voltage V3 of the third cell group G3.

FIG. 7B is a diagram for explaining estimation of the cell voltage Vc of each unit cell C. Here, the estimation of the cell voltage Vc will be described with reference to the example shown in FIG. 7A. The first cell group G1 shown in FIG. 7A includes two unit cells C11, C12 and one dummy cell D11. That is, the number of the unit cells C included in the first cell group G1 is two, and the number of the dummy cells D included therein is one. The second cell group G2 shown in FIG. 7A includes three dummy cells D. That is, the number of the dummy cells D included in the second cell group G2 is three.

The unit amount of voltage drop described above is obtained by dividing the voltage drop V2 due to the second cell group G2 by 3, which is the number of the dummy cells D included in the second cell group G2. Therefore, the unit amount of voltage drop is V2/3. The correction amount described above is obtained by multiplying the unit amount of voltage drop by 1, which is the number of the dummy cells D included in the first cell group G1. Therefore, the correction amount is V2/3. The above-described corrected voltage is obtained by adding the correction amount to the output voltage V1. Therefore, the corrected voltage is V1+V2/3.

The cell voltage Vc is obtained by dividing the corrected voltage by 2, which is the number of the unit cells C included in the first cell group G1. Therefore, the cell voltage Vc is (V1+V2/3)/2. Accordingly, the output voltage V1 output by the first cell group G1 including one or more unit cells C and one or more dummy cell D can be accurately corrected, and the cell voltage Vc of the unit cell C included in the first cell group G1 can thus be estimated.

Concerning the above-described embodiment and modifications, the following Supplementary Notes are further disclosed.

### Supplementary Note 1

The voltage estimation device (10) of the present disclosure includes the voltage acquisition unit (30) that acquires the output voltage (V1) output by the first cell group (G1) containing one or more unit cells (C) and one or more dummy cells (D), the unit cells and the dummy cells being connected in series, the unit cells being configured to generate electric power using a fuel gas and an oxygen-containing gas, the dummy cells being configured not to generate electric power, and the voltage estimation unit (32) that estimates the cell voltage (Vc) of each unit cell (C) based on the output voltage and the unit amount of voltage drop per dummy cell. According to such a configuration, the activation of unnecessary control operation in the fuel cell stack can be suppressed.

### Supplementary Note 2

In the voltage estimation device according to Supplementary Note 1, the unit amount of voltage drop may be obtained by dividing the voltage drop (V2) due to the second cell group (G2) by the number of the dummy cells included in the second cell group, the second cell group containing only the plurality of dummy cells which are connected in series. According to such a configuration, the output voltage of the cell group including one or more unit cells and one or more dummy cells can be accurately corrected, and the cell voltage of the unit cell included in the cell group can be estimated.

### Supplementary Note 3

In the voltage estimation device according to Supplementary Note 1 or 2, the first cell group may include a plurality of the dummy cells, and the voltage estimation unit may estimate the cell voltage using the corrected voltage and the number of the unit cells included in the first cell group, the corrected voltage being a value obtained by adding the correction amount to the output voltage, the correction amount being obtained by multiplying the unit amount of voltage drop by the number of the plurality of dummy cells included in the first cell group. According to such a configuration, the output voltage of the first cell group can be accurately corrected to thereby estimate the cell voltage of the unit cell included in the first cell group.

### Supplementary Note 4

In the voltage estimation device according to Supplementary Note 1 or 2, the first cell group may include one unit cell and one dummy cell, and the voltage estimation unit may estimate the cell voltage by adding the unit amount of voltage drop to the output voltage. According to such a configuration, the cell voltage of the unit cell included in the cell group including one unit cell and one dummy cell can be easily estimated.

### Supplementary Note 5

The voltage estimation device according to Supplementary Note 1 may further include the current acquisition unit (34) configured to acquire the current value of the power generation current (I) of the fuel cell stack (F) including the first cell group, and the setting table in which the unit amount of voltage drop is set in advance in association with the current value of the power generation current, wherein the voltage estimation unit may acquire the unit amount of voltage drop from the setting table based on the current value of the power generation current acquired by the current acquisition unit. According to such a configuration, it is not necessary to provide a voltage measurement circuit for measuring a voltage drop due to a cell group including only dummy cells.

### Supplementary Note 6

The voltage estimation method of the present disclosure includes: the voltage acquisition step of acquiring the output voltage output by the first cell group containing one or more unit cells and one or more dummy cells, the unit cells and the dummy cells being connected in series, the unit cells being configured to generate electric power using a fuel gas and an oxygen-containing gas, the dummy cells being configured not to generate electric power; and the voltage estimation step of estimating the cell voltage of each of the unit cells based on the output voltage and the unit amount of voltage drop per dummy cell. According to such a configuration, the activation of unnecessary control operation in the fuel cell stack can be suppressed.

### Supplementary Note 7

In the voltage estimation method according to Supplementary Note 6, the first cell group may include one unit cell and one dummy cell, and in the voltage estimation step, the cell voltage may be calculated by adding the unit amount of voltage drop to the output voltage. According to such a configuration, the cell voltage of the unit cell included in the cell group including one unit cell and one dummy cell can be easily estimated.

Although the present disclosure has been described in detail, the present disclosure is not limited to the above-described embodiments. In these embodiments, various addition, replacement, changing, partial deletion, and the like can be made without departing from the essence and gist of the present disclosure or without departing from the essence and gist of the present disclosure derived from the contents described in the claims and equivalents thereof. Further, the embodiments can also be implemented together in combination. For example, in the above-described embodiments, the order of each of the operations and the order of each of the processes are illustrated as examples, and the present invention is not necessarily limited to these features. The same applies also in the case that numerical values or mathematical equations are used in the description of the aforementioned embodiments.

1. A voltage estimation device comprising one or more processors that execute computer-executable instructions stored in a memory, wherein the one or more processors execute the computer-executable instructions to cause the voltage estimation device to:
acquire an output voltage output by a first cell group containing one or more unit cells and one or more dummy cells, the unit cells and the dummy cells being connected in series, the unit cells being configured to generate electric power using a fuel gas and an oxygen-containing gas, the dummy cells being configured not to generate electric power; and
estimate a cell voltage of each of the unit cells based on the output voltage and a unit amount of voltage drop per dummy cell.

2. The voltage estimation device according to claim 1, wherein
the unit amount of voltage drop is obtained by dividing a voltage drop due to a second cell group by a number of the dummy cells included in the second cell group, the second cell group containing only the plurality of dummy cells which are connected in series.

3. The voltage estimation device according to claim 1, wherein
the first cell group includes a plurality of the dummy cells, and
the one or more processors cause the voltage estimation device to estimate the cell voltage using a corrected voltage and a number of the unit cells included in the first cell group, wherein the corrected voltage is a value obtained by adding a correction amount to the output voltage, and the correction amount is obtained by multiplying the unit amount of voltage drop by a number of the plurality of dummy cells included in the first cell group.

4. The voltage estimation device according to claim 2, wherein
the first cell group includes a plurality of the dummy cells, and
the one or more processors cause the voltage estimation device to estimate the cell voltage using a corrected voltage and a number of the unit cells included in the first cell group, wherein the corrected voltage is a value obtained by adding a correction amount to the output voltage, and the correction amount is obtained by multiplying the unit amount of voltage drop by a number of the plurality of dummy cells included in the first cell group.

5. The voltage estimation device according to claim 1, wherein
the first cell group includes one of the unit cells and one of the dummy cells, and
the one or more processors cause the voltage estimation device to estimate the cell voltage by adding the unit amount of voltage drop to the output voltage.

6. The voltage estimation device according to claim 2, wherein
the first cell group includes one of the unit cells and one of the dummy cells, and
the one or more processors cause the voltage estimation device to estimate the cell voltage by adding the unit amount of voltage drop to the output voltage.

7. The voltage estimation device according to claim 1, wherein
the one or more processors cause the voltage estimation device to acquire a current value of a power generation current of a fuel cell stack including the first cell group, and
the one or more processors cause the voltage estimation device to acquire the unit amount of voltage drop from a setting table in which the unit amount of voltage drop is set in advance in association with the current value of the power generation current, based on the current value of the power generation current.

8. A voltage estimation method comprising:
acquiring an output voltage output by a first cell group containing one or more unit cells and one or more dummy cells, the unit cells and the dummy cells being connected in series, the unit cells being configured to generate electric power using a fuel gas and an oxygen-containing gas, the dummy cells being configured not to generate electric power; and
estimating a cell voltage of each of the unit cells based on the output voltage and a unit amount of voltage drop per dummy cell.

9. The voltage estimation method according to claim 8, wherein
the first cell group includes one of the unit cells and one of the dummy cells, and
in the estimating of the cell voltage, the cell voltage is calculated by adding the unit amount of voltage drop to the output voltage.
